(19) United States
(12) Patent Application Publication
(10) Pub. No.: US 2026/0205097 A1
(43) Pub. Date: Jul. 16, 2026

(54) SYSTEMS AND METHODS FOR REDUCING HF REFLECTED POWER DURING A CYCLE OF A SQUARE WAVE SIGNAL

(71) Applicant: Lam Research Corporation, Fremont, CA (US)

(72) Inventors: Alexei M. Marakhtanov, Albany, CA (US); Bing Ji, Pleasanton, CA (US); Ranadeep Bhowmick, San Jose, CA (US); Felix Leib Kozakevich, Sunnyvale, CA (US); John P. Holland, San Jose, CA (US)

(21) Appl. No.: 19/138,026

(22) PCT Filed: Dec. 7, 2023
(86) PCT No.: PCT/US23/83005

§ 371 Date: Jun. 11, 2025

Related U.S. Application Data
(60) Provisional application No. 63/432,451, filed on Dec. 14, 2022.

(51) Int. Cl. H03K 3/01; H03K 5/125

(52) U.S. Cl. CPC H03K 3/01; H03K 5/125

(57) ABSTRACT

A method for reducing power reflected towards a high frequency (HF) radio frequency (RF) generator during a cycle of a square wave voltage signal is described. The method includes receiving the square wave voltage signal, and dividing the square wave voltage signal into a pre-determined number of bins including a first bin and a second bin. The first bin has a different time interval than the second bin. The method further includes controlling the HF RF generator to generate an HF RF signal having a first frequency value during the first bin and a second frequency value during the second bin. The first frequency value is different from the second frequency value. The HF RF generator is controlled to reduce the power reflected towards the HF RF generator.

### FIELD

The present embodiments relate to systems and methods for reducing high frequency (HF) reflected power during a cycle of a square wave signal.

### BACKGROUND

In a plasma tool, a radio frequency (RF) generator produces an RF signal. The RF signal is provided via a match to a plasma chamber for processing a semiconductor wafer. In addition to the RF signal, a gas is supplied to the plasma chamber for etching the semiconductor wafer or cleaning the semiconductor wafer or depositing layers on the semiconductor wafer. However, when the RF signal is supplied, inefficiencies in processing the semiconductor wafer occur. Power is reflected towards the RF generator. The reflected power reduces efficiency during processing of the semiconductor wafer, and is undesirable.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Embodiments of the disclosure provide systems, apparatus, methods and computer programs for reducing high frequency (HF) reflected power during a cycle of a square wave signal. It should be appreciated that the present embodiments can be implemented in numerous ways, e.g., a process, an apparatus, a system, a device, or a method on a computer readable medium. Several embodiments are described below.

In one embodiment, a method for reducing power reflected an HF radio frequency (RF) generator during a cycle of a square wave voltage signal is described. The method includes receiving the square wave voltage signal, and dividing the square wave voltage signal into a pre-determined number of bins including a first bin and a second bin. The first bin has a different time interval than the second bin. The method further includes controlling the HF RF generator to generate an HF RF signal having a first frequency value during the first bin and a second frequency value during the second bin. The first frequency value is different from the second frequency value. The HF RF generator is controlled to reduce the power reflected towards the HF RF generator.

In an embodiment, a controller for reducing power reflected towards an HF RF generator during a cycle of a square wave voltage signal is described. The controller includes a processor that receives the square wave voltage signal and divides the square wave voltage signal into a pre-determined number of bins including a first bin and a second bin. The first bin has a different time interval than the second bin. The processor further controls the HF RF generator to generate an HF RF signal having a first frequency value during the first bin and a second frequency value during the second bin. The first frequency value is different from the second frequency value. Also, the HF RF generator is controlled to reduce the power reflected towards the HF RF generator. The controller includes a memory device coupled to the processor.

In one embodiment, a plasma system for reducing power reflected towards an HF RF generator during a cycle of a square wave voltage signal is described. The plasma system includes an LF pulse generator that generates a square wave signal. The plasma system further includes the HF RF generator that generates an RF signal. The plasma system includes a housing coupled to the LF pulse generator and the HF RF generator to receive the square wave signal and the RF signal to output a combined square wave signal. The plasma system also includes a plasma chamber coupled to the housing to receive the combined square wave signal. The plasma system includes a controller coupled to the LF pulse generator and the HF RF generator. The controller receives the square wave voltage signal. The controller further divides the square wave voltage signal into a pre-determined number of bins including a first bin and a second bin. The first bin has a different time interval than the second bin. The controller further controls the HF RF generator to operate at a first frequency value during the first bin and a second frequency value during the second bin. The first frequency value is different from the second frequency value. The HF RF generator is controlled to reduce the power reflected towards the HF RF generator.

Several advantages of the herein described systems and methods include reducing HF reflected power during the cycle of the square wave signal. A frequency of an HF RF generator is controlled during a pre-determined number of bins of each cycle of the square wave signal. The frequency is controlled during each of the bins to reduce the HF reflected power. In addition, the square wave signal has a positive potential short pulse followed by a square-shaped negative potential, which may also include a series of micro pulses. The series of micro pulses is sometimes referred to herein as a flat negative square pulse. The flat negative square pulse creates stability, such as stability in sheath voltage and thickness, in plasma sheath. Due to the stable sheath voltage and thickness, there is less change in plasma impedance, seen by the LF pulse generator and the HF RF generator. The high frequency of the HF RF generator is tuned more quickly and accurately when the change in plasma impedance is less.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system for reducing high frequency (HF) reflected power during e cycle of a square wave signal.

FIG. 2A is a graph to illustrate an embodiment of a clock signal.

FIG. 2B is a graph to illustrate a voltage of the square wave signal versus time.

FIG. 2C is a graph to illustrate an embodiment of a method for reducing power reflected towards an HF RF generator when the square wave signal is supplied.

FIG. 3 is an embodiment of an LF RF pulse generator.

### DETAILED DESCRIPTION

The following embodiments describe systems and methods for reducing high frequency (HF) reflected power during a cycle of a square wave signal. It will be apparent that the present embodiments may be practiced without some or all of these specific details. In other instances, well known operations have not been described in detail in order not to unnecessarily obscure the present embodiments.

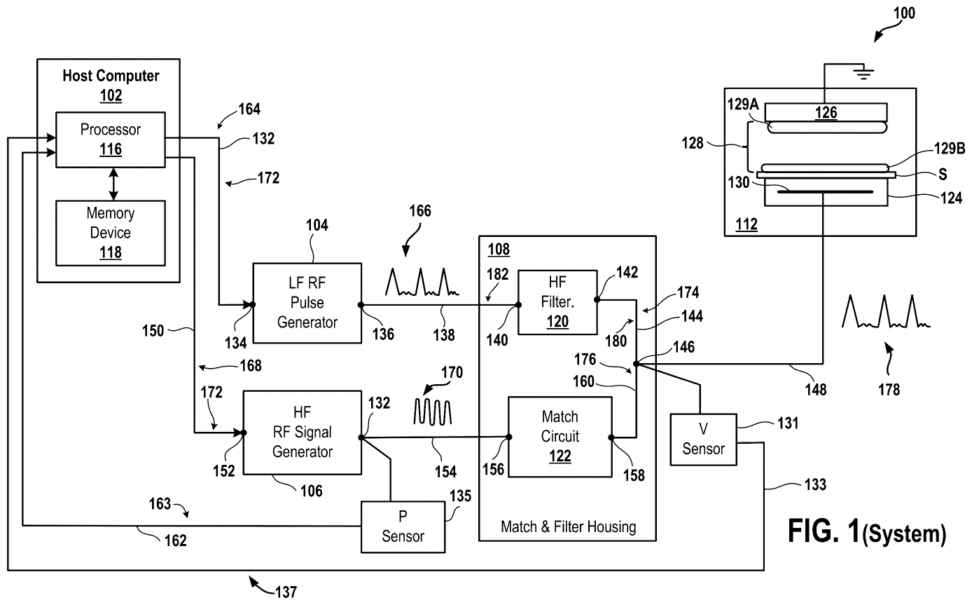

FIG. 1 is a diagram of an embodiment of a system 100 for reducing high frequency (HF) reflected power during a cycle of a square wave signal 166. The square wave signal 166 is sometimes referred to herein as a square pulse waveform. The system 100 includes a host computer 102, a low frequency (LF) radio frequency (RF) pulse generator 104, an HF RF generator 106, a match and filter housing filter 108, and a plasma chamber 112. Examples of the host computer 102 include a desktop computer, a laptop computer, a tablet, a smart phone, and a controller. The host computer 102 includes a processor 116 and a memory device 118. As an example, a processor, as described herein, can be an application specific integrated circuit (ASIC), a central processing unit (CPU), a field programmable gate array (FPGA), a programmable logic device (PLD), an integrated controller, or a microcontroller. Examples of a memory device, as used herein, include a read-only memory (ROM) and a random access memory (RAM). To illustrate, the memory device is a flash memory or a redundant array of independent discs (RAID). The processor 116 is coupled to the memory device 118.

An example of the LF RF pulse generator 104 is a machine that generates multiple high-voltage nanosecond pulses periodically. To illustrate, the LF RF pulse generator is a nanosecond pulser. Each high-voltage nanosecond pulse is sometimes referred to herein as a sub-pulse. Examples of low frequency include frequencies ranging from and including 10 kilohertz (kHz) to 800 kHz. To illustrate, the low frequency is a baseline frequency of 400 kHz. To further illustrate, a frequency of operation of the LF RF pulse generator 104 is 400 kHz. An example of a baseline frequency is a fundamental frequency.

Examples of the high frequency include frequencies ranging from and including 13 megahertz (MHz) to 120 MHz. For example, the high frequency is a baseline frequency of 13.56 MHz or 27 MHz or 40 MHz or 60 MHz or 100 MHz. To illustrate, a frequency of operation of the HF RF generator 106 is 60 MHz. The high frequency is greater than the low frequency. For example, the low frequency is 400 kHz and the high frequency is 60 MHz. As another example, the low frequency is 100 kHz and the high frequency is 60 MHz. An example of the plasma chamber 112 is a capacitively-coupled (CCP) plasma chamber.

The match and filter housing 118 includes an HF filter 120 and a match circuit 122. An example of the HF filter 120 includes an inductor. As another example, the HF filter 120 is not an impedance matching circuit. To illustrate, the HF filter 120 does not match an impedance of a load coupled to an output 142 of the HF filter 120 with an impedance of a source coupled to an input 140 of the HF filter 120. An example of the load coupled to the output 142 includes a combination of an RF connection 144, an output connection 146, an RF transmission line 148, and the plasma chamber 112. An example of the source coupled to the input 140 includes an RF cable 138 and the LF RF pulse generator 104. Another example of the HF filter 120 includes an inductor that is coupled in parallel to a capacitor. Examples of the match circuit 122 include an impedance matching circuit and an impedance matching network. To illustrate, the impedance matching circuit or the impedance matching network has a branch circuit, which includes multiple circuit components, such as capacitors, inductors, and resistors, coupled to each other. To illustrate, two of the circuit components of the match circuit 122 are coupled to each other in a series or in parallel.

The plasma chamber 112 includes a substrate support 124, such as an electrostatic chuck (ESC). The plasma chamber 112 further includes an upper electrode 126 that is located above the substrate support 124 to form a gap 128 between the upper electrode 126 and the substrate support 124. The upper electrode 126 faces the substrate support 124 and is coupled to a ground potential. A lower electrode 130, embedded within the substrate support 124, is made from a metal, such as aluminum or an alloy of aluminum. The substrate support 124 is made from the metal and from a ceramic, such as aluminum oxide (Al₂O₃). The upper electrode 126 is fabricated from the metal.

The system 100 further includes a power sensor 135, which is coupled to an output 132 of the HF RF generator 106. An example of the power sensor 135 includes a sensor that measures delivered power at the output 132. The system 100 also includes a voltage (V) sensor 131 that is coupled to the output 146. The voltage sensor 131 is coupled via a transfer cable 133 to the processor 116. An example of the voltage sensor 131 includes a sensor that measures a voltage of a combined signal 178 at the output 146.

The processor 116 is coupled via a transfer cable 132 to an input 134 of the LF RF pulse generator 104. An example of a transfer cable includes a cable that allows for a serial transfer of data, or a parallel transfer of data, or a transfer of data via a universal serial bus (USB) protocol. The LF RF pulse generator 104 has an output 136 that is coupled via the RF cable 138 to the input 140 of the HF filter 120. For example, the RF cable 138 is coupled to a first end of the inductor of the HF filter 120. As an example, an RF cable includes an RF wire and an RF sheath that surrounds the RF wire.

The HF filter 120 has the output 142 that is coupled via the RF connection 144 to the output connection 146 of the match and filter housing 108. For example, a second end of the inductor of the HF filter 120 is coupled to the RF connection 144. An example of an RF connection, as used herein, is an RF strap or an RF cable. An example of the output connection 146 is a soldering between the RF connection 144 and an RF connection 160. Another example of the output connection 146 is a fastener, such as a screw, and a bolt that connects the RF connections 144 and 160. The output connection 146 is coupled via the RF transmission line 148 to the lower electrode 130. As an example, the RF transmission line 148 includes an RF rod, an insulator material, an RF sheath, and one or more RF straps. The insulator material is located between the RF rod and the RF sheath. The insulator material surrounds the RF rod and the RF sheath surrounds the insulator material. In the example, the RF rod is coupled to the output connection 146. Also, the RF rod is coupled to the output connection 146 via one of the one or more RF straps. The RF rod is coupled to the lower electrode 130.

The processor 116 is also coupled via a transfer cable 150 to an input 152 of the HF RF generator 106. The output 132 of the HF RF generator 106 is coupled via an RF cable 154 to an input 156 of the match circuit 122. For example, a first end of the branch circuit is coupled to the RF cable 154. An output 158 of the match circuit 122 is coupled via the RF connection 160 to the output connection 146. For example, a second end of the branch circuit is coupled to the RF connection 160. The power sensor 130 is coupled via a transfer cable 162 to the processor 116.

The processor 116 generates a recipe signal 164 and sends the recipe signal 164 via the transfer cable 132 and the input 134 to the LF RF pulse generator 104. As an example, the recipe signal 164 includes information, such as a pulse width and a sub-pulse width of the square wave signal 166 to be generated by the LF RF pulse generator 104. As an example, the square wave signal 166 is not a sinusoidal signal and has the low frequency. In the example, an envelope, such as a power level, of the sinusoidal signal is constant or substantially constant. For example, the power level has power amounts within a predetermined range, such as within ±10% from each other. To illustrate, the square wave signal has multiple sub-pulses that repeat periodically and each sub-pulse has the sub-pulse width. Also, in the illustration, the square wave signal has RF voltage ringing and the sinusoidal signal does not have RF voltage ringing. In the illustration, each sub-pulse has a rectangular envelope or a square envelope and the RF voltage ringing is noise, such as a series of micro pulses, that immediately follows the sub-pulse. Further, in the illustration, an envelope of the sub-pulse is substantially greater than an envelope of the RF voltage ringing by a predetermined amount, such as greater than 100%. To further illustrate, a maximum amplitude of the sub-pulse is more than double a maximum amplitude of the RF voltage ringing. The pulse width and the sub-pulse width are further described below. The pulse width provides the low frequency of the square wave signal 166. For example, the low frequency is an inverse of the pulse width.

As an example, the information within the recipe signal 164 does not include a power level, such as a maximum power amplitude, of the square wave signal 166. Rather, in the example, the power level of the sub-pulses of the square wave signal 166 is provided by the sub-pulse width. To illustrate, the greater the sub-pulse width, the lower the power level, and the lower the sub-pulse width, the higher the power level. As an example, the information within the recipe signal 164 is received from a user via an input device that is coupled to the processor 116. Examples of the input device include a keyboard, a mouse, a stylus, and a keypad. An example of a power level is a maximum amplitude or a peak-to-peak amplitude.

Moreover, the processor 116 generates a recipe signal 168 and sends the recipe signal 168 via the transfer cable 150 and the input 152 to the HF RF generator 106. As an example, the recipe signal 168 includes information, such as the high frequency and a power level, of an RF signal 170 to be generated by the HF RF generator 106. The power level sent within the recipe signal 168 is a supplied power level. The RF signal 170 has the high frequency. The power sensor 135 measures delivered power of the RF signal 170 to generate a power signal 163 and sends the power signal 163 via the transfer cable 162 to the processor 116. An example of the power signal 163 is a signal that includes delivered power of the RF signal 170.

Upon receiving the recipe signal 164, a processor of the LF RF pulse generator 104 stores the information within the recipe signal 164 in a memory device of the LF RF pulse generator 104. The processor of the LF RF pulse generator 104 is coupled to the memory device of the LF RF pulse generator 104 and the processor and the memory device are parts of a controller of the LF RF pulse generator 104.

Similarly, upon receiving the recipe signal 168, a processor of the HF RF generator 106 stores the information within the recipe signal 168 in a memory device of the HF RF generator 106. The processor of the HF RF generator 106 is coupled to the memory device of the HF RF generator 106.

Moreover, the processor 116 generates and sends a trigger signal 172 via the transfer cable 164 and the input 134 to the processor of the LF RF pulse generator 104. Also, the trigger signal 172 is sent from the processor 116 via the transfer cable 150 and the input 152 to the processor of the HF RF generator 106. For example, the processor 116 sends the trigger signal 172 to both the LF RF pulse generator 104 and the HF RF generator 106 simultaneously.

Upon receiving the trigger signal 172, the processor of the LF RF pulse generator 104 accesses the information stored within the memory device of the LF RF pulse generator 104, and controls multiple signal components of the LF RF pulse generator 104 based on the information to generate the square wave signal 166. For example, the square wave signal 166 is generated to have the pulse width and the sub-pulse width received within the recipe signal 164 from the processor 116. The signal components of the LF RF pulse generator 104 are further described below. An example of the square wave signal 166 is a signal having multiple sub-pulses, such as square pulses, that repeat periodically according to the pulse width. Each square pulse has the sub-pulse width.

In a similar manner, in response to receiving the trigger signal 172, the processor of the HF RF generator 106 accesses the information stored within the memory device of the HF RF generator 106, and controls multiple signal components of the HF RF generator 106 based on the information to generate the RF signal 170. For example, the RF signal 170 is generated to have the power level and high frequency received within the recipe signal 168 from the processor 116. An example of the RF signal 170 is a sinusoidal signal, such as a sinusoidal waveform having multiple sine waves that repeat periodically.

Examples of the signal components of the HF generator 106 include a driver and amplifier system, and an RF power supply. The driver and amplifier system includes a driver and an amplifier, and the driver is coupled to the amplifier. An example of the driver is one or more transistors and an example of the RF power supply is an RF oscillator. The amplifier is coupled to the RF power supply, which is coupled to the RF cable 154. When the trigger signal 172 is received, the processor of the HF RF generator 106 generates a command signal having the information stored within the memory device of the HF RF generator 106 and sends the command signal to the driver. The driver generates a current signal based on the information received within the command signal and sends the current signal to the amplifier. The amplifier amplifies the current signal to output an amplified signal, and sends the amplified signal to the RF power supply. Upon receiving the amplified signal, the RF power supply generates the RF signal 170 having the power level and high frequency of the information received within the command signal.

The signal components of the LF RF pulse generator 104 send the square wave signal 166 via the output 136, the RF cable 138, and the input 140 to the HF filter 120. For example, the square wave signal 166 is received at the first end of the inductor of the HF filter 120. The HF filter 120 modifies an impedance of the square wave signal 166 to output a modified square wave signal 174 at its output. For example, the modified square wave signal 174 is output at the second end of the inductor of the HF filter 120. As an example, the modified square wave signal 174 is not a sinusoidal signal. The modified square wave signal 174 is sent from the output 142 via the RF connection 144 to the output connection 146.

Furthermore, the signal components of the HF RF generator 106 send the RF signal 170 via the output 132, the RF cable 154, and the input 156 to the match circuit 122. For example, the RF signal 170 is received at the first end of the branch circuit. The match circuit 122 matches an impedance of a load coupled to the output 158 with an impedance of a source coupled to the input 156 to output a modified RF signal 176 at the output 158. For example, the branch circuit matches the impedance of the load coupled to the output 158 with the impedance of the source coupled to the input 156 to modify an impedance of the RF signal 170 to provide the modified RF signal 176 at the second end of the branch circuit. An example of the load coupled to the output 158 includes a combination of the RF connection 160, the RF output connection 146, the RF transmission line 148, and the plasma chamber 112. An example of the source coupled to the input 156 includes a combination of the RF cable 154 and the HF RF generator 106. The modified RF signal 176 is sent from the output 158 via the RF connection 160 to the output connection 146.

A first portion of the modified RF signal 176 is combined, such as summed, with the modified square wave signal 174 at the output connection 146 to provide the combined signal 178 at the output connection 146. For example, an amplitude of the first portion of the modified RF signal 176 and an amplitude of the modified square wave signal 174 are summed at the output connection 146. As an example, the combined signal 178 is a square wave signal and not a sinusoidal signal.

In addition, a second portion 180 of the modified RF signal 176 is reflected from the output connection 146 via the RF connection 144 towards the HF filter 120. The second portion 180 has the high frequency. The HF filter 120 filters out the high frequency from the second portion 180 of the modified RF signal 176 to provide a reflected filtered signal 182 at the input 140. When the high frequency is filtered from the second portion 180, the reflected filtered signal 182 does not damage the signal components and the processor of the LF RF pulse generator 104. The reflected filtered signal 182 is reflected via the RF cable 138 towards the LF RF pulse generator 104.

The combined signal 178 is sent via the RF rod of the RF transmission line 148 to the electrode 130. As an example, power of the combined signal 178 is represented as a square wave signal having power fluctuations of the high frequency of the first portion of the modified RF signal 176. Also, the voltage of the combined signal 178 is measured by the voltage sensor 131 to generate a voltage signal 137, which is sent via the transfer cable 133 to the processor 116. The voltage signal 137 is sometimes referred to herein as a square wave voltage signal. When one or more process gases, such an oxygen containing gas, or a fluorine containing gas, or a combination thereof, are supplied to the gap 128 in addition providing the combined signal 178 to the electrode 130, plasma is stricken or maintained within the gap 128. The plasma is bordered by a top plasma sheath 129A and a bottom plasma sheath 129B. The plasma processes a substrate S, such as a semiconductor wafer, that is placed on the substrate support 124. Examples of processing the substrate S include etching the substrate S, depositing materials on the substrate S, and cleaning the substrate S. Use of the LF RF pulse generator 104 with the HF RF generator 106 facilitates faster frequency tuning of the HF RF generator 106 compared to when an LF RF signal generator (not shown) is used with the HF RF generator 106. The LF RF signal generator generates a sinusoidal RF signal of the low frequency instead of the square pulse waveform.

In an embodiment, the terms RF ringing and RF voltage ringing are used herein interchangeably.

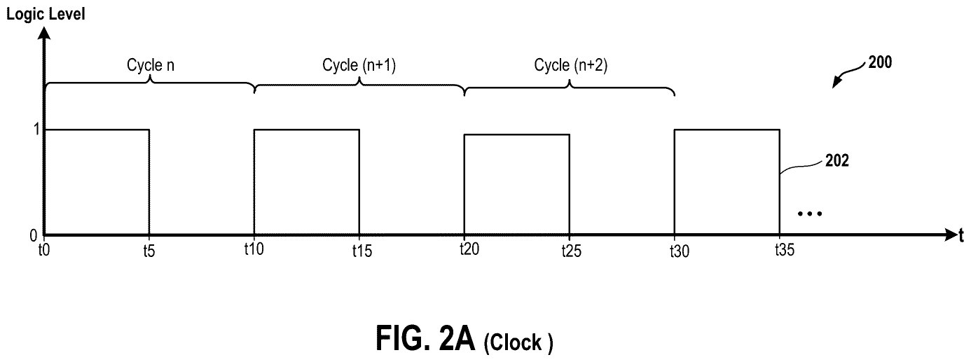

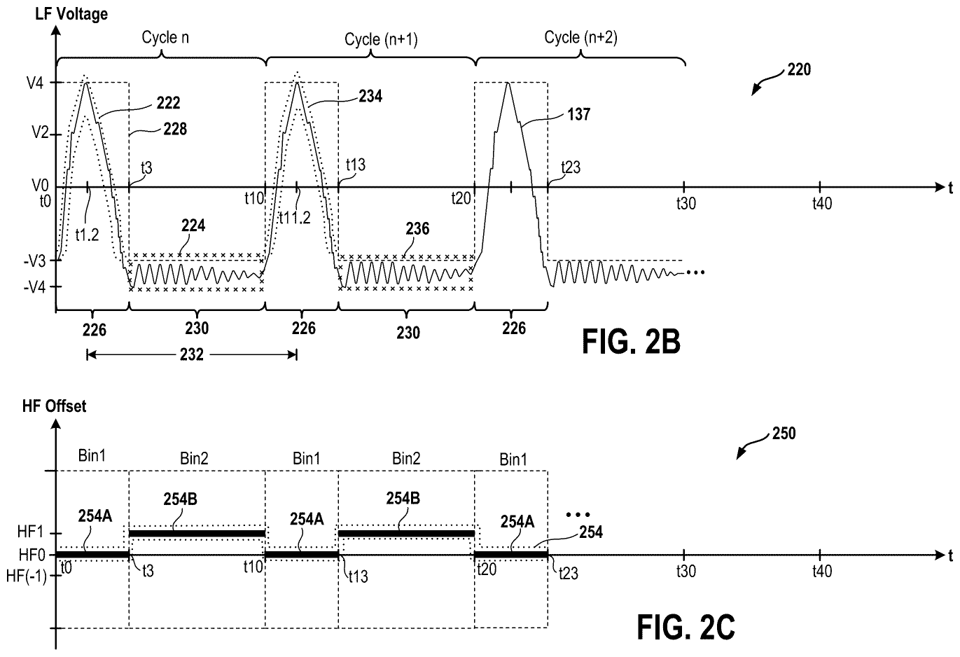

FIG. 2A is a graph 200 to illustrate an embodiment of a clock signal 202. The clock signal 202 is generated by the processor 116 (FIG. 1) and sent via the transfer cable 132 to the processor of the LF RF pulse generator 104 (FIG. 1). The processor of the LF RF pulse generator 104 controls the signal components of the LF RF pulse generator 104 in synchronization with the clock signal 202. Also, the clock signal 202 is sent via the transfer cable 150 (FIG. 1) to the processor of the HF RF generator 106 (FIG. 1). The processor of the HF RF generator 106 controls the signal components of the HF RF generator 106 in synchronization with the clock signal 202.

The graph 200 plots logic levels of the clock signal 202 versus time t. The logic levels are plotted on a y-axis of the graph 200 and the time t is plotted on an x-axis of the graph 200. The time t increases in a positive x-direction of the x-axis from a time t0 to a time t30. It should be noted that a time interval between two consecutive times on the x-axis of the graph 200 is equal to a time interval between any other two consecutive times on the x-axis. For example, a first time interval between the times t0 and t5 is equal to a second time interval between the times t5 and t10. As another example, a time interval between the times t0 and t1 is equal to a time interval between the times t1 and t2 and a time interval between the times t2 and t3.

The clock signal 202 periodically transitions between a logic level 1 and a logic level 0. For example, during a cycle n of the clock signal 202, the clock signal 202 is at the logic level 1 from a time t0 to a time t5, where n is an integer greater than zero. Also, during the cycle n, at the time t5, the clock signal 202 transitions from the logic level 1 to the logic level 0. Further, during the cycle n, the clock signal 202 remains at the logic level 0 from the time t5 to the time t10. The logic levels 1 and 0 repeat in this manner during a cycle (n+1) of the clock signal 202 and during a cycle (n+2) of the clock signal 202.

It should be noted that as illustrated in the graph 220, each cycle of the clock signal 202 is also a cycle of the square wave signal 166. For example, the clock signal 202 and the square wave signal 166 are synchronized with each other. To illustrate, the cycle n of the clock signal 202 is also the cycle n of the square wave signal 166, the cycle (n+1) of the clock signal 202 is also the cycle (n+1) of the square wave signal 166, and the cycle (n+2) of the clock signal 202 is also the cycle (n+2) of the square wave signal 166. To further illustrate, a sub-pulse and a consecutively following RF voltage ringing of the square wave signal 166 repeat periodically to generate the cycles n, (n+1), and so on of the square wave signal 166.

FIG. 2B is a graph 220 to illustrate a voltage of the square wave signal 166 that is generated by the LF RF pulse generator 104 (FIG. 1) versus the time t. The voltage of the square wave signal 166 is represented as the voltage signal 137 and is plotted on a y-axis of the graph 220 and the time t is plotted on an x-axis of the graph 220. For example, the voltage of the voltage signal 137 primarily represents a voltage of the square wave signal 166. To illustrate, the voltage of the voltage signal 137 includes the voltage of the square wave signal 166 and a voltage of the RF signal 170 (FIG. 1) generated by the HF RF generator 106. In the illustration, the voltage of the square wave signal 166 is substantially greater than the voltage of the RF signal 170. To further illustrate, the voltage of the RF signal 170 is negligible compared to the voltage of the square wave signal 166.

The x-axis of the graph 220 is the same as the x-axis of the graph 200 (FIG. 2A). Voltage values of the voltage signal 137 range from −V4 to V4. The voltage values increase from −V4 to V4. For example, the voltage value −V3 is greater than the voltage value −V4 and the voltage value −V2 is greater than the voltage value −V3. Also, a difference between any two consecutive voltage values of the graph 220 is equal. For example, a difference between the voltage values −V3 and −V4 is equal to a difference between the voltage values −V2 and −V3.

The voltage of the voltage signal 137 has a sub-pulse 222 and RF voltage ringing 224 during the cycle n. The sub-pulse 222 has a sub-pulse width 226, such as a time interval ranging from the time t0 to the time t3. At the time to, the sub-pulse 222 has the voltage value −V3 and at the time t3, the sub-pulse 222 has the voltage value −V3. The sub-pulse 222 has the voltage value −V3 at the time to and transitions up from the voltage value −V3 to the voltage value V4 during a time interval from the time t0 to the time t1.2. The sub-pulse 222 has the voltage value V4, which is a peak value, such as a maximum amplitude, of the sub-pulse 222. The sub-pulse 222 further transitions down from the voltage value V4 to the voltage value −V3 during a time interval from the time t1.2 to the time t3. The sub-pulse 222 is enclosed by an envelope 228, which is rectangular-shaped. By controlling the sub-pulse width 226, the envelope 228 becomes square-shaped. As an example, the sub-pulse width of any sub-pulse of the voltage signal 137 ranges from 10 nanoseconds (ns) to 500 ns and a rise time of each sub-pulse of the square wave signal 166 is about 50 ns. To illustrate, each sub-pulse of the voltage signal 137 has a rise time that ranges from 40 ns to 60 ns.

The sub-pulse 222 is immediately followed by the RF voltage ringing 224. The RF voltage ringing 224 has a ringing width 230, which is greater than the sub-pulse width 226. It should be noted that the ringing width 230 represents a ringing width of the square signal signal 166 during the cycle n. For example, the ringing width 230 is of the square wave signal 166. The RF voltage ringing 224 occurs during a time interval from the time t3 to the time t10. The RF voltage ringing 224 occurs during a greater time interval than the sub-pulse width 226 of the sub-pulse 222. The RF voltage ringing 224 is a series of micro pulses and each micro pulse has a smaller amplitude than an amplitude of the sub-pulse 222. For example, a maximum amplitude of the sub-pulse is V4 and a maximum amplitude of the RF voltage ringing 224 is −V3. Also, each micro pulse of the RF voltage ringing 224 has a smaller micro pulse width than the sub-pulse width 226 of the sub-pulse 222. An example of the micro pulse width is a time interval of occurrence of a micro pulse of the voltage signal 137. An example of an amplitude is a maximum amplitude or a peak-to-peak amplitude. In this manner, a sub-pulse and a series of micro pulses repeat periodically during each of the cycles (n+1) and (n+2) of the clock signal 202.

It should be noted that, as an example, each sub-pulse of the voltage signal 137 has the same sub-pulse width 226 or substantially the same sub-pulse width. For example, the sub-pulse widths of the sub-pulses of the voltage signal 137 range within ±10% from each other. Also, the micro pulse width is outside the range of the sub-pulse width of the voltage signal 137. For example, the micro pulse width is substantially less than the sub-pulse width of the voltage signal 137. As another example, the micro pulse width of the RF voltage ringing 224 reduces with a progression of the RF voltage ringing 224.

The voltage signal 137 also has a pulse width 232, which is a width between maximum amplitudes of two consecutive sub-pulses of the voltage signal 137. For example, the pulse width 232 is a time interval between the time t1.2 at which the sub-pulse 222 has the voltage value V4 and the time t11.2 at which a consecutive sub-pulse 234 has the voltage value V4.

It should be noted that the pulse width 232 represents a pulse width of the voltage signal 137 between any two consecutive ones of the cycles n, (n+1), and so on. For example, the pulse width 232 is of the voltage signal 137. In the example, the pulse width 232 remains substantially the same between any two consecutive ones of the cycles n, (n+1), and so on. To illustrate, the pulse width 232 between the cycles (n+1) and n is within ±10% from the pulse width 232 between the cycles (n+2) and (n+1).

The voltage of the voltage signal 137 has the sub-pulse 234 and RF voltage ringing 236 during the cycle (n+1). The sub-pulse 234 has the voltage value V4, which is a peak value, such as a maximum amplitude, of the sub-pulse 234. The sub-pulse 234 is immediately followed by the RF voltage ringing 236 during the cycle (n+1). The sub-pulse 234 also has the sub-pulse width 226 and the RF voltage ringing 236 also has the ringing width 230.

FIG. 2C is a graph 252 to illustrate an embodiment of a method for reducing power reflected towards the HF RF generator 106 (FIG. 1) when the square wave signal 166 (FIG. 1) is supplied. The power reflected towards the HF RF generator 106 is sometimes referred to herein as high frequency reflected power. The high frequency reflected power is power that is reflected from the plasma chamber 112 via the RF sheath of the RF transmission line 148, the output connection 146, the RF connection 160, a housing of the match circuit 122, and the RF sheath of the RF cable 154 towards the HF RF generator 106.

The graph 252 includes a plot 254, which plots HF offsets, such as frequency values, of the HF RF signal 170 (FIG. 1) versus the time t. The plot 254 is split into two portions 254A and 254B during each cycle of the clock signal 202 (FIG. 2A). For example, the plot 254 is split into the portions 254A and 254B during the cycle n and also during the cycle (n+1).

The time t is plotted on an x-axis of the graph 252 and the HF offsets are plotted on a y-axis of the graph 252. The x-axis of the graph 252 is the same as the x-axis of the graph 220 (FIG. 2B).

The y-axis of the graph 252 plots the HF offsets, such as HF offset values HF1 and HF−1. The HF offsets are offset from a reference frequency value HF0, such as a fundamental frequency, of the HF RF signal 170. For example, the HF offset value HF1 is a result of a sum of a positive real number and the reference frequency value HF0 and the HF offset value HF(−1) is a result of a subtraction of the positive real number from the reference frequency value HF0. The portion 254A has the reference frequency value HF0 and the portion 254B has the HF offset value HF1.

The x-axis of the graph 252 is divided into bins 1 and 2 during each cycle of the clock signal 202. For example, the x-axis of the graph 252 is divided into the bins 1 and 2 during the cycle n and into the bins 1 and 2 during the cycle (n+1). Each bin of a cycle of the clock signal 202 is a time interval of the cycle. For example, the bin 1 represents a time interval between the times to and t3 during the cycle n of the clock signal 202 and the bin 2 represents a time interval between the times t3 and t10 during the cycle n of the clock signal 202. The bin 2 has a greater time interval than the time interval of the bin 1.

The cycle n has the time interval from the time t0 to the time t10. As such, the bins 1 and 2 occupy the entire time interval from the time t0 to the time t10. Similarly, the bins 1 and 2 occupy the entire time interval for each cycle of the clock signal 202.

The processor 116 (FIG. 1) divides the voltage signal 137 into a pre-determined number of bins, such as the bins 1 and 2, for each cycle of the clock signal 202. For example, the processor 116 compares a time interval of the sub-pulse 222 with the sub-pulse width, received within the recipe signal 164 (FIG. 1), for the square wave signal 164. In the example, upon determining that the time interval is equal to the sub-pulse width received within the recipe signal 164, the processor 116 designates the time interval to be the bin 1 of each cycle of the voltage signal 137. Moreover, in the example, the processor 116 calculates a difference between a time interval of each cycle of the clock signal 202 and the sub-pulse width to determine a ringing width. In the example, the processor 116 designates the ringing width to be the bin 2 of each cycle of the voltage signal 137.

In the example, the processor 116 designates the time interval between the times t0 and t3 during which the voltage signal 137 has the sub-pulse 222 as the bin 1 of the cycle n, and designates the time interval between the times t3 and t10 during which the voltage signal 137 has the RF voltage ringing 224 as the bin 2 of the cycle n. Similarly, as another example, the processor 116 designates the time interval between the times t10 and t13 during which the voltage signal 137 has the sub-pulse 234 as the bin 1 of the cycle (n+1), and designates the time interval between the times t13 and t20 during which the voltage signal 137 has the RF voltage ringing 236 as the bin 2 of the cycle (n+1).

The processor 116 determines that the HF RF generator 106 is to be controlled to operate at the reference frequency value HF0 during the bin 1 of each cycle n, (n+1), and so on, and is to be controlled to operate at the HF offset value HF1 during the bin 2 of each cycle n, (n+1), and so on, as follows. During the bin 1 of a cycle q, such as a cycle (n−m) or the cycle n, of the clock signal 202, the processor 116 controls the HF RF generator 106 to operate at a first frequency offsetting value, where m is a positive integer less than n, and q is a positive integer. As an example, a frequency offsetting value is sometimes referred to herein as an empirical frequency value. The first frequency offsetting value is a frequency of the HF RF signal 170 generated by the HF RF generator 106 during the cycle q. Further, during the bin 1 of the cycle q, the processor 116 receives power values of the power signal 163 (FIG. 1) from the power sensor 135 (FIG. 1) and determines reflected power of the HF RF signal 170 from the power values. For example, the processor 116 calculates a first statistical value, such as a median or an average, from the power values received during the bin 1 of the cycle q. In the example, the first statistical value is a value of delivered power of the HF RF signal 170. Further, in the example, the processor 116 computes a difference between supplied power of the HF RF signal 170 and the first statistical value to determine a first reflected power value. The supplied power is forward power of the HF RF signal 170. Also, the supplied power is the power level received from the user via the input device.

During the bin 1 of a cycle r, such as a cycle (n−m+p) or the cycle n, of the clock signal 202, the processor 116 controls the HF RF generator to operate at the reference frequency value HF0, where p and r are positive integers, and (n−m+p) is greater than (n−m) but less than n. The reference frequency value HF0 is a frequency of the HF RF signal 170 generated by the HF RF generator 106 during the cycle r. Further, during the bin 1 of the cycle r, the processor 116 receives power values of the power signal 163 from the power sensor 135 and determines reflected power of the HF RF signal 170 from the power values. For example, the processor 116 calculates a second statistical value, such as a median or an average, from the power values received during the bin 1 of the cycle r. In the example, the second statistical value is a value of delivered power of the HF RF signal 170. Also, in the example, processor 116 computes a difference between the supplied power of the HF RF signal 170 and the second statistical value to determine a second reflected power value.

Thereafter, the processor 116 compares the second reflected power value with the first reflected power value to determine whether the second reflected power value is less than the first reflected power value. Upon determining that the second reflected power value is less than the first reflected power value, the processor 116 determines to control the HF RF generator 106 operate at the reference frequency value HF0 instead of the first frequency offsetting value during the bin 1 of the cycles n, (n+1) and so on.

To control the HF RF generator 106 operate at the reference frequency value HF0, the processor 116 sends the recipe signal 168 having the reference frequency value HF0 via the transfer cable 150 (FIG. 1) and the input 152 to the HF RF generator 106. Moreover, the processor 116 includes an instruction within the recipe signal 168 to generate the HF RF signal 170 having the reference frequency value HF0 for the time period of the bin 1 of each of the cycles n, (n+1) and so on. After receiving the reference frequency value HF0 and the instruction and in response to receiving the trigger signal 172 (FIG. 1), the HF RF generator 106 generates the RF signal 170 having the reference frequency value HF0 for the time period of the bin 1 during each of the cycles n, (n+1) and so on.

Moreover, during the bin 2 of the cycle q of the clock signal 202, the processor 116 controls the HF RF generator 106 to operate at a second frequency offsetting value. The second frequency offsetting value is a frequency of the HF RF signal 170 generated by the HF RF generator 106 during the cycle q. Further, during the bin 2 of the cycle q, the processor 116 receives power values of the power signal 163 (FIG. 1) from the power sensor 135 (FIG. 1) and determines reflected power of the HF RF signal 170 from the power values. For example, the processor 116 calculates a third statistical value, such as a median or an average, from the power values received during the bin 2 of the cycle q. In the example, the third statistical value is a value of delivered power of the HF RF signal 170. Further, in the example, the processor 116 computes a difference between the supplied power of the HF RF signal 170 and the third statistical value to determine a third reflected power value.

Furthermore, during the bin 2 of the cycle r of the clock signal 202, the processor 116 controls the HF RF generator to operate at the HF offset value HF1. The HF offset value HF1 is a frequency of the HF RF signal 170 generated by the HF RF generator 106 during the cycle r. Further, during the bin 2 of the cycle r, the processor 116 receives power values of the power signal 163 from the power sensor 135 and determines reflected power of the HF RF signal 170 from the power values. For example, the processor 116 calculates a fourth statistical value, such as a median or an average, from the power values received during the bin 2 of the cycle r. In the example, the fourth statistical value is a value of delivered power of the HF RF signal 170. Also, in the example, the processor 116 computes a difference between the supplied power of the HF RF signal 170 and the fourth statistical value to determine a fourth reflected power value.

Then, the processor 116 compares the third reflected power value with the fourth reflected power value to determine whether the fourth reflected power value is less than the third reflected power value. Upon determining that the fourth reflected power value is less than the third reflected power value, the processor 116 determines to control the HF RF generator 106 to operate at the HF offset value HF1 instead of the second frequency offsetting value during the bin 2 of the cycles n, (n+1) and so on.

To control the HF RF generator 106 to operate at the HF offset value HF1, the processor 116 sends the recipe signal 168 having the HF offset value HF1 via the transfer cable 150 and the input 152 to the HF RF generator 106. Moreover, the processor 116 includes an instruction within the recipe signal 168 to generate the HF RF signal 170 having the HF offset value HF1 for the time interval of the bin 2 of the cycles n, (n+1) and so on. After receiving the HF offset value HF1 and the instruction and in response to receiving the trigger signal 172, the HF RF generator 106 generates the RF signal 170 having the HF offset value HF1 for the time period of the bin 2 during each of the cycles n, (n+1) and so on.

In one embodiment, the processor 116 controls the HF RF generator 106 to operate at a first range of HF values during the bin 1 of each of the cycles n, (n+1) and so on and at a second range of HF offset values during the bin 2 of each of the cycles n, (n+1) and so on. As an example, the first range of HF values includes the reference frequency value HF0 and additional frequency values, such as HF offset values, and the second range of HF offset values includes the HF offset value HF1 and additional HF offset values. Further in the example, the first range is exclusive of the second range. To illustrate, each HF value of the first range is unequal to any of the HF offset values of the second range. Also, in the embodiment, the processor 116 controls, during the bin 1 of the cycle r, the HF RF generator 106 to operate at the first range of HF values. When the HF RF generator 106 is controlled to operate at the first range, the processor 116 receives the power values from the P sensor 135 and calculates the second statistical value from the power values. The processor 116 compares the second statistical value with the first statistical value to determine that the second statistical value is less than the first statistical value. After determining that the second statistical value is less than the first statistical value, the processor 116 controls the HF RF generator 106 to operate at the first range of HF values during the bin 1 of each of the cycles n, (n+1), and so on. To control the HF RF generator 106 operate at the first range of HF values, the processor 116 sends the recipe signal 168 having the first range of HF values via the transfer cable 150 and the input 152 to the HF RF generator 106. Moreover, the processor 116 includes an instruction within the recipe signal 168 to generate the HF RF signal 170 having the first range of HF values for the time period of the bin 1 of the cycles n, (n+1) and so on. After receiving the first range of HF values and the instruction and in response to receiving the trigger signal 172, the HF RF generator 106 generates the RF signal 170 having the first range of HF values for the time period of the bin 1 during each of the cycles n, (n+1) and so on.

Further, in the embodiment, the processor 116 controls, during the bin 2 of the cycle r, the HF RF generator 106 to operate at the second range of HF offset values. When the HF RF generator 106 is controlled to operate at the second range, the processor 116 receives the power values from the P sensor 135 and calculates the fourth statistical value from the power values. The processor 116 compares the fourth statistical value with the third statistical value to determine that the fourth statistical value is less than the third statistical value. The processor 116 controls the HF RF generator 106 to operate at the second range of HF offset values during the bin 2 of each of the cycles n, (n+1), and so on. To control the HF RF generator 106 operate at the second range of HF offset values, the processor 116 sends the recipe signal 168 having the second range via the transfer cable 150 and the input 152 to the HF RF generator 106. Moreover, the processor 116 includes an instruction within the recipe signal 168 to generate the HF RF signal 170 having the second range for the time period of the bin 2 of the cycles n, (n+1) and so on. After receiving the second range of HF offset values and the instruction and in response to receiving the trigger signal 172, the HF RF generator 106 generates the RF signal 170 having the second range for the time period of the bin 2 during each of the cycles n, (n+1) and so on.

In an embodiment, instead of controlling the HF RF generator 106 to generate the RF signal 170 during the bin 1 of each of the cycles n, (n+1), and so on, the HF RF generator 106 is controlled to be turned off during the bin 1. For example, the processor 116 does not determine the first and second reflected power values for the bin 1 of the cycles q and r. Also, in the example, the processor 116 does not control the HF RF generator 106 to generate the RF signal 170 having the reference frequency value HF0 during the bin 1 of the cycles n, (n+1) and so on. Rather, in the example, the processor 116 includes, within the recipe signal 168, the power level of zero of the RF signal 170 and an instruction that the power level is to be maintained at zero for the time period of the bin 1 of the cycles n, (n+1), and so on. In the example, upon receiving the instruction and the power level of zero, the HF RF generator 106 generates the RF signal 170 having the power level of zero during the bin 1 of the cycles n, (n+1), and so on. It should be noted that when the HF RF generator 106 is turned off, the high frequency of operation of the HF RF generator 106 and the high frequency of the RF signal 170 are zero.

In one embodiment, instead of power reflected towards the HF RF generator 106, a voltage standing wave ratio (VSWR) or a voltage reflection coefficient (gamma) is used. The VSWR or the reflection coefficient represents the power reflected towards the HF RF generator 106. The power reflected towards the HF RF generator 106, the VSWR, and the voltage reflection coefficient are examples of a reflection parameter associated with the HF RF generator 106.

In an embodiment, instead of the HF offset value HF1, any other HF offset value, such as HF2 or HF3 is used. The HF offset value HF3 is greater than the HF offset value HF2 and the HF offset value HF2 is greater than the HF offset value HF1. Each HF offset value HF2 and HF3 is generated by adding a respective frequency value to the reference frequency value HF0.

In an embodiment, instead of the reference frequency value HF0, an HF offset value, such as HF(−1) or HF(−2) is used. The HF reference frequency value HF0 is greater than the HF offset value HF(−1) and the HF offset value HF(−1) is greater than the HF offset value HF(−2). Each HF offset value HF(−2) and HF(−1) is generated by subtracting a respective frequency value to the reference frequency value HF0.

In an embodiment, the pre-determined number of bins is only two, such as the bin 1 and the bin 2 only. For example, the voltage signal 137 is not divided into more than two bins.

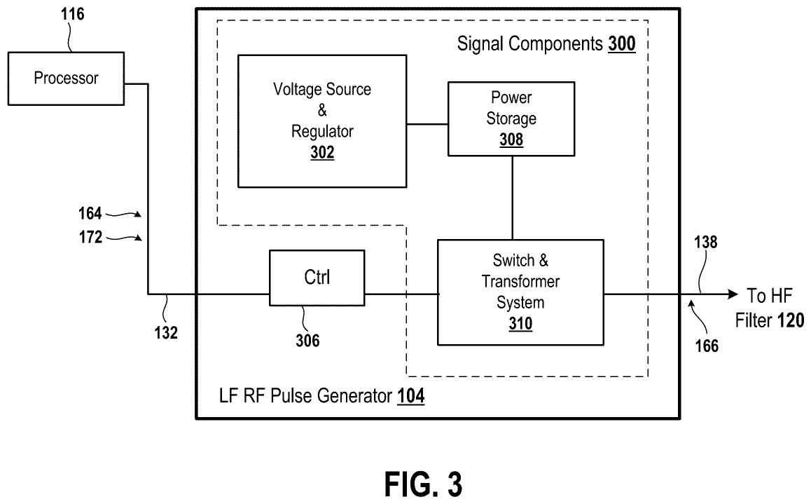

FIG. 3 is an embodiment of the LF RF pulse generator 104. The LF RF pulse generator 104 includes signal components 300 and a controller 306. The signal components 300 include a voltage and source regulator 302, a power storage 308, and a switch and transformer system 310. As an example, RF voltage ringing, as described herein, is noise due to one or more of the signal components 300.

An example of the voltage source and regulator 302 includes a combination of a voltage supply, such as a direct current (DC) voltage supply, and a voltage regulator, such as a variable resistor. The voltage supply is coupled to the voltage regulator. An example of the switch and transformer system 310 includes a combination of a switch, such as a solid-state switch, and a transformer. An illustration of the solid-state switch is a transistor or a group of transistors. The solid-state switch is coupled to the transformer. As an example, the transformer includes a primary winding and a secondary winding. An example of the power storage 308 includes a capacitor.

An example of the controller 306 includes the processor and the memory device. The processor of the controller 306 is coupled to the memory device of the controller 306. As another example, the controller 306 is an ASIC or a PLD.

The processor 116 is coupled to the processor of the controller 306 via the transfer cable 132. The processor of the controller 306 is coupled to the switch of the switch and transformer system 310. The voltage regulator of the voltage source and regulator 302 is coupled to the power storage 308.

Moreover, the power storage 308 is coupled to the transformer and the switch is coupled to the transformer. For example, the power storage 308 is coupled to a first end of the primary winding and the switch is coupled to a second end of the primary winding. The secondary winding of the transformer is coupled to the RF cable 138.

Upon receiving the information within the recipe signal 164 from the processor 116, the processor of the controller 306 stores the information within the memory device of the controller 306. The voltage supply generates a voltage signal and supplies the voltage signal to the voltage regulator. The voltage regulator regulates the voltage signal, such as maintains the voltage signal to match a pre-determined voltage signal, to output a regulated voltage signal, and sends the regulated voltage signal to the power storage 308. The power storage 308 stores a charge according to the regulated voltage signal.

Moreover, in response to receiving the trigger signal 172 from the processor 116, the processor of the controller 306 accesses the sub-pulse width 226 (FIG. 2C) of the voltage signal 137 (FIG. 1) from the memory device of the controller 306, generates an on command signal, and sends the on command signal to the switch. When the on command signal is received, the switch turns on and a switch current signal generated to discharge the charge stored in the power storage 308 is supplied to the primary winding of the transformer for the time period of the sub-pulse width 226. The secondary winding transforms, such as increases or decreases, an amount of voltage of the switch current signal to a different amount to output a transformed amount of voltage to start generating the sub-pulse 222 (FIG. 2C). The transformed amount of voltage is a voltage of the sub-pulse 222.

At the end of the time period of the sub-pulse width 226, the processor of the controller 306 generates an off command signal, and sends the off command signal to the switch. Upon receiving the off command signal, the switch turns off and the supply of the switch current signal to the primary winding stops. When the supply of the switch current signal stops, the voltage applied by the switch current signal drops to reduce the voltage across the primary winding. When the voltage across the primary winding reduces, the transformed amount of voltage reduces to end the generation of the sub-pulse 222 to output a reduced transformed amount of voltage. The reduced transformed amount of voltage is of the RF voltage ringing 230 (FIG. 2C).

The processor of the controller 306 controls the switch to be off until an end of the cycle n of the clock signal 202 (FIG. 2A). After the end of the cycle n and at a beginning of the cycle (n+1), the processor of the controller 306 controls the switch to be turned back on for the time period of the sub-pulse width 226 to generate the sub-pulse 234 (FIG. 2B). In this manner, multiple sub-pulses and multiple RF voltage ringings of the square wave signal 166 are generated to further generate multiple sub-pulses and multiple RF voltage ringings of the voltage signal 137 (FIG. 2B).

It should be noted that although the above-embodiments are described with reference to a square wave signal, in some embodiments, the terms triangular wave signal, saw-tooth shaped signal, and square wave signal are used herein interchangeably.

Embodiments described herein may be practiced with various computer system configurations including hand-held hardware units, microprocessor systems, microprocessor-based or programmable consumer electronics, minicomputers, mainframe computers and the like. The embodiments can also be practiced in distributed computing environments where tasks are performed by remote processing hardware units that are linked through a network.

In some embodiments, a controller is part of a system, which may be part of the above-described examples. Such systems include semiconductor processing equipment, including a processing tool or tools, chamber or chambers, a platform or platforms for processing, and/or specific processing components (a wafer pedestal, a gas flow system, etc.). These systems are integrated with electronics for controlling their operation before, during, and after processing of a semiconductor wafer or substrate. The electronics is referred to as the “controller,” which may control various components or subparts of the system or systems. The controller, depending on the processing requirements and/or the type of system, is programmed to control any of the processes disclosed herein, including the delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks coupled to or interfaced with a system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer system, which allows for remote access of the wafer processing. The computer enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to a system over a network, which includes a local network or the Internet. The remote computer includes a user interface that enables entry or programming of parameters and/or settings, which are then communicated to the system from the remote computer. In some examples, the controller receives instructions in the form of data, which specify the parameters, factors, and/or variables for each of the processing steps to be performed during one or more operations. It should be understood that the parameters, factors, and/or variables are specific to the type of process to be performed and the type of tool that the controller is configured to interface with or control. Thus as described above, the controller is distributed, such as by including one or more discrete controllers that are networked together and working towards a common purpose, such as the processes and controls described herein. An example of a distributed controller for such purposes includes one or more integrated circuits on a chamber in communication with one or more integrated circuits located remotely (such as at the platform level or as part of a remote computer) that combine to control a process on the chamber.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

As noted above, depending on the process step or steps to be performed by the tool, the host computer communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These operations are those physically manipulating physical quantities. Any of the operations described herein that form part of the embodiments are useful machine operations.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations may be processed by a computer selectively activated or configured by one or more computer programs stored in a computer memory, cache, or obtained over the computer network. When data is obtained over the computer network, the data may be processed by other computers on the computer network, e.g., a cloud of computing resources.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment, described above, are combined with one or more features of any other embodiment, also described above, without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A method for reducing power reflected towards a high frequency (HF) radio frequency (RF) generator during a cycle of a square wave voltage signal, comprising:
receiving the square wave voltage signal;
dividing the square wave voltage signal into a pre-determined number of bins including a first bin and a second bin, wherein the first bin has a different time interval than the second bin;
controlling the HF RF generator to generate an HF RF signal having a first frequency value during the first bin and a second frequency value during the second bin, wherein the first frequency value is different from the second frequency value, wherein said controlling the HF RF generator occurs to reduce the power reflected towards the HF RF generator.

2. The method of claim 1, wherein the square wave voltage signal has a peak during the first bin and has RF ringing during the second bin.

3. The method of claim 1, wherein the different time interval is a smaller time interval than a time interval of the second bin, wherein the first and second bins occupy an entire time interval of a cycle of the square wave voltage signal.

4. The method of claim 1, further comprising:
determining a first statistical power value after operating the HF RF generator at the first frequency value during the first bin;
determining a second statistical power value after operating the HF RF generator at a first empirical frequency value during the first bin;
comparing the first statistical power value with the second statistical power value;
controlling the HF RF generator to operate at the first frequency value upon determining that the first statistical power value is less than the second statistical power value.

5. The method of claim 4, further comprising:
determining a third statistical power value after operating the HF RF generator at the second frequency value during the second bin;
determining a fourth statistical power value after operating the HF RF generator at a second empirical frequency value during the second bin;
comparing the third statistical power value with the fourth statistical power value;
controlling the HF RF generator to operate at the second frequency value upon determining that the third statistical power value is less than the fourth statistical power value.

6. The method of claim 1, wherein said controlling the HF RF generator to have the first frequency value includes controlling the HF RF generator to be turned off during the first bin.

7. The method of claim 1, wherein said controlling the HF RF generator comprises controlling the HF RF generator to generate a first range of frequency values during the first bin and a second range of frequency values during the second bin, wherein the first range includes the first frequency value and a third frequency value, and the second range includes the second frequency value and a fourth frequency value.

8. The method of claim 7, wherein the third frequency value is different from the fourth frequency value and the first frequency value, and the fourth frequency value is different from the second frequency value.

9. A controller for reducing power reflected towards a high frequency (HF) radio frequency (RF) generator during a cycle of a square wave voltage signal, comprising:
a processor configured to:
receive the square wave voltage signal;
divide the square wave voltage signal into a pre-determined number of bins including a first bin and a second bin, wherein the first bin has a different time interval than the second bin;
control the HF RF generator to generate an HF RF signal having a first frequency value during the first bin and a second frequency value during the second bin, wherein the first frequency value is different from the second frequency value, wherein the HF RF generator is controlled to reduce the power reflected towards the HF RF generator; and
a memory device coupled to the processor.

10. The controller of claim 9, wherein the square wave voltage signal has a peak during the first bin and has RF ringing during the second bin.

11. The controller of claim 9, wherein the different time interval is a smaller time interval than a time interval of the second bin, wherein the first and second bins occupy an entire time interval of a cycle of the square wave voltage signal.

12. The controller of claim 9, wherein the processor is configured to:
determine a first statistical power value after operating the HF RF generator at the first frequency value during the first bin;
determine a second statistical power value after operating the HF RF generator at a first empirical frequency value during the first bin;
compare the first statistical power value with the second statistical power value;
control the HF RF generator to operate at the first frequency value upon determining that the first statistical power value is less than the second statistical power value.

13. The controller of claim 12, wherein the processor is configured to:
determine a third statistical power value after operating the HF RF generator at the second frequency value during the second bin;
determine a fourth statistical power value after operating the HF RF generator at a second empirical frequency value during the second bin;
compare the third statistical power value with the fourth statistical power value;
control the HF RF generator to operate at the second frequency value upon determining that the third statistical power value is less than the fourth statistical power value.

14. The controller of claim 9, wherein the HF RF generator is controlled to be turned off during the first bin.

15. The controller of claim 9, wherein the HF RF generator is controlled to generate a first range of frequency values during the first bin and a second range of frequency values during the second bin, wherein the first range includes the first frequency value and a third frequency value, and the second range includes the second frequency value and a fourth frequency value.

16. The controller of claim 15, wherein the third frequency value is different from the fourth frequency value and the first frequency value, and the fourth frequency value is different from the second frequency value.

17. A plasma system for reducing power reflected towards a high frequency (HF) radio frequency (RF) generator during a cycle of a square wave voltage signal, the plasma system comprising:
a low frequency (LF) pulse generator configured to generate a square wave signal;
the HF RF generator configured to generate an RF signal;
a housing coupled to the LF pulse generator and the HF RF generator to receive the square wave signal and the RF signal to output a combined square wave signal;
a plasma chamber coupled to the housing to receive the combined square wave signal; and
a controller coupled to the LF pulse generator and the HF RF generator, wherein the controller is configured to:
receive the square wave voltage signal;
divide the square wave voltage signal into a pre-determined number of bins including a first bin and a second bin, wherein the first bin has a different time interval than the second bin;
control the HF RF generator to operate at a first frequency value during the first bin and a second frequency value during the second bin, wherein the first frequency value is different from the second frequency value, wherein the HF RF generator is controlled to reduce the power reflected towards the HF RF generator.

18. The plasma system of claim 17, wherein the square wave voltage signal has a peak during the first bin and has RF ringing during the second bin, wherein the different time interval is a smaller time interval than a time interval of the second bin, wherein the first and second bins occupy an entire time interval of a cycle of the square wave voltage signal.

19. The plasma system of claim 9, wherein the controller is configured to:
determine a first statistical power value after operating the HF RF generator at the first frequency value during the first bin;
determine a second statistical power value after operating the HF RF generator at a first empirical frequency value during the first bin;
compare the first statistical power value with the second statistical power value;
control the HF RF generator to operate at the first frequency value upon determining that the first statistical power value is less than the second statistical power value.

20. The plasma system of claim 19, wherein the controller is configured to:
determine a third statistical power value after operating the HF RF generator at the second frequency value during the second bin;
determine a fourth statistical power value after operating the HF RF generator at a second empirical frequency value during the second bin;
compare the third statistical power value with the fourth statistical power value;
control the HF RF generator to operate at the second frequency value upon determining that the third statistical power value is less than the fourth statistical power value.
